(19) United States
(12) Patent Application Publication
(10) Pub. No.: US 2021/0407713 A1
(43) Pub. Date: Dec. 30, 2021

(54) MODIFIED SINTERED Nd-Fe-B MAGNET, AND PREPARATION METHOD AND USE THEREOF

(71) Applicants: GRIREM ADVANCED MATERIALS CO., LTD., Beijing (CN); GRIREM HI-TECH CO., LTD., Langfang (CN); GRIREM (RONGCHENG) CO., LTD., Weihai (CN)

(72) Inventors: Yang LUO, Beijing (CN); Wei ZHU, Beijing (CN); Dunbo YU, Beijing (CN); Zilong WANG, Beijing (CN); Hongbin ZHANG, Beijing (CN); Xinyuan BAI, Beijing (CN); Xiao LIN, Beijing (CN); Haijun PENG, Beijing (CN); Jiajun XIE, Beijing (CN)

(21) Appl. No.: 17/331,555

(22) Filed: May 26, 2021

(30) Foreign Application Priority Data
Jun. 29, 2020 (CN) 202010608039.7

(51) Int. Cl. H01F 1/057; C22C 38/00

(52) U.S. Cl. CPC H01F 1/0577; C22C 2202/02; C22C 38/005

(57) ABSTRACT

The present invention relates to a modified sintered Nd—Fe—B magnet, and a preparation method and a use thereof. The modified sintered Nd—Fe—B magnet is prepared by performing grain boundary diffusion on a matrix, wherein the matrix is a sintered Nd—Fe—B magnet; a grain boundary diffusion source for the grain boundary diffusion consists of a first diffusion source and a second diffusion source; the first diffusion source is a PrMx alloy, M being at least one selected from a group consisted of Cu, Al, Zn, Mg, Ga, Sn, Ag, Pb, Bi, Ni, Nb, Mn, Co, Fe, Ti, Cr, Zr, Mo and Ge; and the second diffusion source is heavy rare earth Dy and/or Tb. A wider and longer diffusion channel formed by a low-melting-point alloy containing Pr preferentially entering the inside of the magnet is used as a channel for rapid diffusion of a heavy rare earth element

### CROSS-REFERENCE TO RELATED APPLICATION

This Application claims priority from the Chinese patent application 202010608039.7 filed Jun. 29, 2020, the content of which is incorporated herein in the entirety by reference.

### TECHNICAL FIELD

The present invention relates to a modified sintered neodymium-iron-boron (Nd—Fe—B) magnet, and a preparation method and a use thereof, and relates to the technical field of rare earth permanent magnet materials.

### BACKGROUND

A sintered Nd—Fe—B permanent magnet is widely applied to fields such as wind power generation, energy-saving home appliances, and new energy vehicles on its excellent comprehensive magnetic property. With the continuous progress of manufacturing technology and the improvement of people's awareness of environmental protection, the magnet has attracted much attention from the market in three fields of energy conservation and environmental protection, new energy, and new energy vehicles. Its consumption is growing rapidly by 10-20% every year, showing a good application prospect.

For the magnet, coercivity is an important index for evaluating a magnetic property of the Nd—Fe—B permanent magnet material. Heavy rare earth elements Dy and Tb, as important elements for improving the coercivity, may effectively increase anisotropy constants of a 2:14:1 phase magnetocrystalline, but their prices are higher. Thus, the coercivity is generally increased by deposition and diffusion of the heavy rare earth elements Dy and Tb on the surface to reduce a manufacturing cost of the magnet. However, a concentration of the heavy rare earth element decreases greatly from a surface of the magnet toward the inside of the magnet and a diffusion depth is relatively low, resulting in limited property improvement.

Chinese application No. 201910183289.8 discloses that a low-melting-point pure metal of Cu, Al, Zn, Mg or Sn, or a low-melting-point alloy of CuAl, CuSn, CuZn, CuMg, SnZn, MgAl, MgCu, MgZn, AlMgZn or CuAlMg is deposited on a surface of a magnet by magnetron sputtering or evaporation, and heavy rare earth Dy or Tb is deposited on the surface of the magnet by evaporation or magnetron sputtering. However, this method can only improve the coercivity of the magnet by about 37%, and fails to further improve the coercivity of the magnet.

### SUMMARY

An objective of the present invention is to provide a modified sintered Nd—Fe—B magnet, in which a wider and longer diffusion channel formed by a low-melting-point alloy containing Pr preferentially entering the inside of the magnet is used as a channel for rapid diffusion of a heavy rare earth element, such that a diffusion depth and a diffusion rate of the heavy rare earth element are further increased, coercivity of the magnet is improved, and manufacturing cost is reduced.

A modified sintered Nd—Fe—B magnet is prepared by performing grain boundary diffusion on a matrix, wherein the matrix is a sintered Nd—Fe—B magnet; a grain boundary diffusion source for the grain boundary diffusion consists of a first diffusion source and a second diffusion source; the first diffusion source is a PrMₓ alloy, M is at least one selected from a group consisted of Cu, Al, Zn, Mg, Ga, Sn, Ag, Pb, Bi, Ni, Nb, Mn, Co, Fe, Ti, Cr, Zr, Mo and Ge, X represents a mass percentage and is 8 to 90, and the balance is Pr and an unavoidable impurity; and the second diffusion source is heavy rare earth Dy and/or Tb.

In the present invention, diffusion of the first diffusion source is earlier than that of the second diffusion source during the grain boundary diffusion.

Optionally, a mass ratio of the matrix, the first diffusion source, and the second diffusion source is 100: 0.1-2: 0.1-1.

Optionally, in the modified sintered Nd—Fe—B magnet, crystal grains are equiaxed crystals, and a crystal grain size is 2 μm to 20 μm.

Optionally, in the modified sintered Nd—Fe—B magnet, a grain boundary phase includes a thin-layer grain boundary phase located between two crystal grains, the thin-layer grain boundary phase is distributed between the crystal grains in a region within 50 μm from a diffusion surface of the sintered Nd—Fe—B magnet, a boundary between the crystal grains is clear, and a width of the thin-layer grain boundary phase is 50 nm to 500 nm.

Optionally, in the region within 50 μm from the diffusion surface of the sintered Nd—Fe—B magnet, the crystal grains are core-shell structure grains, and a thickness of a shell layer of the core-shell structure grain is 0.1 μm to 2.0 μm.

In a second aspect of the present invention, there is provided a preparation method of a modified sintered Nd—Fe—B magnet. The preparation method at least includes the following steps:

(1) preparing an alloy film layer on a surface of a sintered Nd—Fe—B magnet, wherein the alloy film layer is PrMₓ, M is at least one selected from a group consisted of Cu, Al, Zn, Mg, Ga, Sn, Ag, Pb, Bi, Ni, Nb, Mn, Co, Fe, Ti, Cr, Zr, Mo and Ge, X represents a mass percentage and is 8 to 90, and the balance is Pr and an unavoidable impurity;

(2) preparing a heavy rare earth film layer on the surface of the alloy film layer acquired in (1), wherein heavy rare earth includes Dy (T_{M}=1412° C.) and/or Tb (T_{M}=1356° C.); and

(3) acquiring the modified sintered Nd—Fe—B magnet by performing grain boundary diffusion on the sintered Nd—Fe—B magnet by using the alloy film layer and the heavy rare earth film layer as a diffusion source.

Preferably, M is at least one selected from a group consisted of Cu, Al, Zn, Ga, Fe, Ni, and Co.

Optionally, the sintered Nd—Fe—B magnet is a sintered Nd—Fe—B magnet in a sintered state or in a tempered state.

Optionally, a melting point of the alloy film layer in (1) is 400° C. to 700° C.

Optionally, a thickness of the alloy film layer in (1) is 1 μm to 40 μm, preferably 5 μm to 20 μm.

Optionally, said preparing the alloy film layer in (1) specifically includes:

depositing the alloy film layer by adopting magnetron sputtering technology and using a PrMₓ alloy as a target material under a condition that a vacuum degree is lower than 2×10⁻³ Pa.

Optionally, a thickness of the heavy rare earth film layer in (2) is 1 μm to 20 μm, preferably 3 μm to 10 μm.

Optionally, said preparing the heavy rare earth film layer in (2) specifically includes:

depositing the heavy rare earth film layer by adopting a magnetron sputtering method and using heavy rare earth as a target material under a condition that a vacuum degree is lower than 2×10⁻³ Pa.

Optionally, a specific condition for the grain boundary diffusion in (3) includes:

a vacuum degree being lower than 3×10⁻³ Pa;

a diffusion temperature being 750° C. to 1000° C.;

diffusion duration being 0.5 h to 24 h.

Further, after the grain boundary diffusion, tempering treatment is performed at 430° C. to 640° C. for 0.5 h to 10 h.

Preferably, a diffusion temperature is 850° C. to 950° C.; and

diffusion duration is 2 h to 24 h.

Optionally, a mass ratio of the sintered Nd—Fe—B magnet, the alloy film layer and the heavy rare earth film layer is 100:0.1-2:0.1-1.

In a specific embodiment, a method for improving a magnetic property of a sintered Nd—Fe—B magnet includes the following steps:

1) cleaning surfaces of the sintered Nd—Fe—B magnet, and ensuring that the upper and lower surfaces of the sintered Nd—Fe—B magnet are smooth and flat;

2) depositing a low-melting-point alloy PrM containing Pr on the surfaces of the magnet under a condition that a vacuum degree is lower than 2×10⁻³Pa, wherein a thickness of a deposited layer is 1 μm to 40 μm, preferably 5 μm to 20 μm;

3) depositing heavy rare earth Dy (T_{M}=1412° C.) or Tb (T_{M}=1356° C.) on the surfaces of the magnet, wherein a thickness of the deposited layer is 1 μm to 20 μm;

4) placing the treated magnet into a tempering furnace and vacuumizing the latter, and keeping a temperature in the tempering furnace at 850° C. to 950° C. for 2 h to 24 h while a vacuum degree therein is lower than 3×10⁻³ Pa; and

5) keeping a temperature in the tempering furnace at 430° C. to 640° C. for 0.5 h to 10 h.

Optionally, in the modified sintered Nd—Fe—B magnet, crystal grains are equiaxed crystals, and a crystal grain size is 2 μm to 20 μm. In the present invention, the crystal grain size refers to the maximum distance between two points within a crystal plane with the largest surface area in a crystal grain, namely, a length of the long axis of the crystal grain.

Optionally, the grain boundary phase includes a thin-layer grain boundary phase located between two crystal grains and a trifurcated grain boundary phase located at corners of multiple crystal grains; and the thin-layer grain boundary phase is uniformly distributed between the crystal grains in a region within 50 μm from a diffusion surface of the sintered Nd—Fe—B magnet, a boundary between the crystal grains is clear, and a width of the thin-layer grain boundary phase is 50 nm to 500 nm.

In the present invention, the diffusion surface of the sintered Nd—Fe—B magnet refers to the surface thereof with an alloy film layer and a heavy rare earth film layer; the region within 50 μm from the diffusion surface of the sintered Nd—Fe—B magnet refers to a region where a vertical distance to the diffusion surface is less than or equal to 50 μm; and the width of the thin-layer grain boundary phase refers to the shortest distance between adjacent crystal grains.

Optionally, in the region within 50 μm from the diffusion surface of the sintered Nd—Fe—B magnet, the crystal grains are core-shell structure grains, and a thickness of a shell layer of the core-shell structure grain is 0.1 μm to 2.0 μm.

In the present invention, the shell layer is a main phase epitaxial layer containing Tb and/or Dy.

In a third aspect of the present invention, there is provided a use of the modified sintered Nd—Fe—B magnet prepared by any one of the above preparation methods, or any one of the modified sintered Nd—Fe—B magnets in fields of wind power generation, energy-saving home appliances and new energy vehicles.

The present invention has the following beneficial effects.

(1) In the solution of the present invention, a wider and longer diffusion channel formed by the low-melting-point alloy containing Pr preferentially entering the inside of the magnet is used as a channel for rapid diffusion of the heavy rare earth element, such that a diffusion depth and a diffusion rate of the heavy rare earth element are further increased, and the coercivity of the magnet is improved.

(2) The method can reduce the consumption of the heavy rare earth element, such that the cost is significantly reduced while improving the coercivity of the magnet.

(3) The method is simple in process, easy to implement, and broad in application prospect.

### BRIEF DESCRIPTION OF THE DRAWINGS

FIG. 1 is a scanning electron microscope photograph of a high-coercivity magnet after grain boundary diffusion prepared in Embodiment 1.

FIG. 2 is a scanning electron microscope photograph of an unmodified sintered Nd—Fe—B magnet in Embodiment 1.

### DETAILED DESCRIPTION

To enable those skilled in the art to better understand the technical solutions of the present invention, the technical solutions of the present invention will be described clearly and completely in conjunction with the accompanying drawings of the present invention. Other similar embodiments acquired by those of ordinary skill in the art based on embodiments of the present invention without creative labor shall fall within the protection scope of the present invention. In addition, the directional terms mentioned in the following embodiments, such as “upper”, “lower”, “left” and “right”, only refer to the directions with reference to the accompanying drawings. Therefore, the used directional terms are used to illustrate but not limit the present invention. All features disclosed in the description or steps in all disclosed methods or processes, except mutually exclusive features and/or steps, may be combined in any way. Unless specifically stated, any feature disclosed in the description (including any additional claim, abstract and accompanying drawing) may be replaced with other equivalent or alternative features with similar purposes. That is, unless specifically stated, each feature is only one example of a series of equivalent or similar features.

In the present invention, unless otherwise specified, raw materials are all conventional commercial products.

A modified sintered Nd—Fe—B magnet is prepared by performing grain boundary diffusion on a matrix, wherein the matrix is a sintered Nd—Fe—B magnet; a grain boundary diffusion source for the grain boundary diffusion consists of a first diffusion source and a second diffusion source; the first diffusion source is a PrM alloy, M is at least one selected from a group consisted of Cu, Al, Zn, Mg, Ga, Sn, Ag, Pb, Bi, Ni, Nb, Mn, Co, Fe, Ti, Cr, Zr, Mo and Ge, X represents a mass percentage and is 8 to 90, and the balance is Pr and an unavoidable impurity; and the second diffusion source is heavy rare earth Dy and/or Tb.

In the present invention, diffusion of the first diffusion source is earlier than that of the second diffusion source during the grain boundary diffusion.

Optionally, a mass ratio of the matrix, the first diffusion source, and the second diffusion source is 100:0.1-2:0.1-1.

Optionally, in the modified sintered Nd—Fe—B magnet, crystal grains are equiaxed crystals, and a crystal grain size is 2 μm to 20 μm.

Optionally, in the modified sintered Nd—Fe—B magnet, a grain boundary phase comprises a thin-layer grain boundary phase located between two crystal grains, the thin-layer grain boundary phase is distributed between the crystal grains in a region within 50 μm from a diffusion surface of the sintered Nd—Fe—B magnet, a boundary between the crystal grains is clear, and a width of the thin-layer grain boundary phase is 50 nm to 500 nm.

Optionally, in the region within 50 μm from the diffusion surface of the sintered Nd—Fe—B magnet, the crystal grains are core-shell structure grains, and a thickness of a shell layer of the core-shell structure grain is 0.1 μm to 2.0 μm.

A preparation method of a modified sintered Nd—Fe—B magnet at least includes the following steps:

(1) preparing an alloy film layer on a surface of a sintered Nd—Fe—B magnet, wherein the alloy film layer is PrMx, M is at least one selected from a group consisted of Cu, Al, Zn, Mg, Ga, Sn, Ag, Pb, Bi, Ni, Nb, Mn, Co, Fe, Ti, Cr, Zr, Mo and Ge, X represents a mass percentage and is 8 to 90, and the balance is Pr and an unavoidable impurity;

(2) preparing a heavy rare earth film layer on the surface of the alloy film layer acquired in (1), wherein heavy rare earth includes Dy (T_{M}=1412° C.) and/or Tb (T_{M}=1356° C.); and

(3) acquiring the modified sintered Nd—Fe—B magnet by performing grain boundary diffusion on the sintered Nd—Fe—B magnet by using the alloy film layer and the heavy rare earth film layer as a diffusion source.

Preferably, M is at least one selected from a group consisted of Cu, Al, Zn, Ga, Fe, Ni, and Co.

Optionally, the sintered Nd—Fe—B magnet is a sintered Nd—Fe—B magnet in a sintered state or in a tempered state.

Optionally, a melting point of the alloy film layer in (1) is 40° C. to 700° C.

Optionally, a thickness of the alloy film layer in (1) is 1 μm to 40 μm, preferably 5 μm to 20 μm.

Optionally, said preparing the alloy film layer in (1) specifically includes:

depositing the alloy film layer by adopting magnetron sputtering technology and using a PrMₓ alloy as a target material under a condition that a vacuum degree is lower than 2×10⁻³ Pa.

Optionally, a thickness of the heavy rare earth film layer in (2) is 1 μm to 20 μm, preferably 3μm to 10 μm.

Optionally, said preparing the heavy rare earth film layer in (2) specifically includes:

depositing the heavy rare earth film layer by adopting a magnetron sputtering method and using heavy rare earth as a target material under a condition that a vacuum degree is lower than 2×10⁻³ Pa.

Optionally, a specific condition for the grain boundary diffusion in (3) includes:

a vacuum degree being lower than 3×10⁻³ Pa;

a diffusion temperature being 750° C. to 1000° C.; and

diffusion duration being 0.5 h to 24 h.

Further, after the grain boundary diffusion, tempering treatment is performed at 430° C. to 640° C. for 0.5 h to 10 h.

Preferably, the diffusion temperature is 850° C. to 950° C.; and

the diffusion duration is 2 h to 24 h.

Optionally, a mass ratio of the sintered Nd—Fe—B magnet, the alloy film layer and the heavy rare earth film layer is 100:0.1-2:0.1-1.

In a specific embodiment, a method for improving a magnetic property of a sintered Nd—Fe—B magnet includes the following steps:

1) cleaning surfaces of the sintered Nd—Fe—B magnet, and ensuring that the upper and lower surfaces of the sintered Nd—Fe—B magnet are smooth and flat;

2) depositing a low-melting-point alloy PrM containing Pr on the surfaces of the magnet under a condition that a vacuum degree is lower than 2×10⁻³ Pa, wherein a thickness of a deposited layer is 1 μm to 40 μm, preferably 5 μm to 20 μm;

3) depositing heavy rare earth Dy (T_{M}=1412° C.) or Tb (T_{M}=1355° C.) on the surfaces of the magnet, wherein a thickness of the deposited layer is 1 μm to 20 μm;

4) placing the treated magnet placed into a tempering furnace and vacuumizing the latter, and keeping a temperature in the tempering furnace at 850° C. to 950° C. for 2 h to 24 h while a vacuum degree therein is lower than 3×10⁻³ Pa; and

5) keeping a temperature in the tempering furnace at 430° C. to 640° C. for 0.5 h to 10 h.

Optionally, in the modified sintered Nd—Fe—B magnet, crystal grains are equiaxed crystals, and a crystal grain size is 2 μm to 20 μm. In the present invention, the crystal grain size refers to the maximum distance between two points within a crystal plane with the largest surface area in a crystal grain, namely, a length of the long axis of the crystal grain.

Optionally, the grain boundary phase includes a thin-layer grain boundary phase located between two crystal grains and a trifurcated grain boundary phase located at corners of multiple crystal grains; and the thin-layer grain boundary phase is uniformly distributed between the crystal grains in a region within 50 μm from a diffusion surface of the sintered Nd—Fe—B magnet, a boundary between the crystal grains is clear, and a width of the thin-layer grain boundary phase is 50 nm to 500 nm.

Here, in the present invention, the diffusion surface of the sintered Nd—Fe—B magnet refers to the surface thereof with an alloy film layer and a heavy rare earth film layer; the region within 50 μm from the diffusion surface of the sintered Nd—Fe—B magnet refers to a region where a vertical distance to the diffusion surface is less than or equal to 50 μm; and the width of the thin-layer grain boundary phase refers to the shortest distance between adjacent crystal grains.

Optionally, in the region within 50 μm from the diffusion surface of the sintered Nd—Fe—B magnet, the crystal grains are core-shell structure grains, and a thickness of a shell layer of the core-shell structure grain is 0.1 μm to 2.0 μm.

In the present invention, the shell layer is a main phase epitaxial layer containing Tb and/or Dy.

There is provided a use of the modified sintered Nd—Fe—B magnet prepared by any one of the above preparation methods, or any one of the modified sintered Nd—Fe—B magnets in fields of wind power generation, energy-saving home appliances and new energy vehicles.

### Embodiment 1

(1) A sintered Nd—Fe—B magnet with the composition of (PrNd)_{27.67}Fe_{68.71}B_{0.97}Al_{0.19}Co_{0.82}Cu_{0.16}Ga_{0.18}Tb_{0.64} (wt.%), namely, a sintered Nd—Fe—B magnet with the grade of 48H, is sliced into 8*8*7 mm blocks.

(2) The surfaces of the sintered Nd—Fe—B magnet block are cleaned, and it is ensured that the upper and lower polar surfaces of the sintered Nd—Fe—B magnet block are smooth and flat.

(3) Magnetron sputtering is performed on the upper and lower polar surfaces of the sintered Nd—Fe—B magnet block by using an alloy Pr₉₂Al₈(wt. %) with a melting point of 850° C. as a target material when a vacuum degree is 1×10⁻³ Pa to form an alloy film layer with a thickness of 6 μm on each of the upper and lower polar surfaces.

(4) Heavy rare earth Tb is deposited on the surface of each alloy film layer by magnetron sputtering technology when a vacuum degree is 1×10⁻³ Pa to acquire a heavy rare earth film layer with a thickness of 3 μm, wherein at this time, a mass ratio of the sintered Nd—Fe—B magnet, the alloy Pr₉₂Al₈ and the heavy rare earth is 100:0.3:0.3.

(5) A temperature at 920° C. is kept for 4 h and tempering is performed at 500° C. for 2 h when a vacuum degree is 2×10⁻³ Pa to acquire a high-coercivity sintered Nd—Fe—B magnetic material marked as material 1.

### Embodiment 2

(1) A sintered Nd—Fe—B magnet with the composition of (PrNd)_{27.67}Fe_{68.71}B_{0.97}Al_{0.19}Co_{0.82}Cu_{0.16}Ga_{0.18}Tb_{0.64} (wt. %) is sliced into 8*8*7 mm blocks.

(2) The surfaces of the sintered Nd—Fe—B magnet block are cleaned, and it is ensured that the upper and lower polar surfaces of the sintered Nd—Fe—B magnet block are smooth and flat.

(3) Magnetron sputtering is performed on the upper and lower polar surfaces of the sintered Nd—Fe—B magnet block by using an alloy Pr₆₀Ga₄₀ (wt. %) with a melting point of 550 ° C. as a target material when a vacuum degree is 1×10⁻³ Pa to form an alloy film layer with a thickness of 6 μm on each of the upper and lower polar surfaces.

(4) Heavy rare earth Tb is deposited on the surface of each alloy film layer by magnetron sputtering technology when a vacuum degree is 1×10⁻³ Pa to acquire a heavy rare earth film layer with a thickness of 3 μm.

(5) A temperature at 900° C. is kept for 4 h and tempering is performed at 520° C. for 2 h when a vacuum degree is 2×10⁻³ Pa to acquire a high-coercivity sintered Nd—Fe—B magnetic material marked as material 2.

### Embodiments 3 to 10

The preparation methods in Embodiments 3 to 10 are mostly the same as that in Embodiment 1, and differences are shown in Table 1. Materials acquired therefrom are marked as materials 3 to 10 sequentially.

TABLE 1
Table of Preparation Conditions for Each of Embodiments

| | Sintered | | Heavy rare | Diffusion | Tempering |
|---|---|---|---|---|---|
| | Nd—Fe—B | Alloy layer/ | earth layer/ | temperature ° C./ | temperature ° C./ |
| Embodiment | magnet | thickness μm | thickness μm | duration h | duration h |
| Embodiment 1 | 48H | Pr₉₂Al₈/6 | Tb/3 | 920/4 | 500/2 |
| Embodiment 2 | 48H | Pr₆₀Ga₄₀/6 | Dy/3 | 900/4 | 520/2 |
| Embodiment 3 | 48H | Pr₇₀Cu₃₀/10 | Tb/4 | 920/4 | 500/2 |
| Embodiment 4 | 48H | Pr₆₀Al₂₀Cu₂₀/10 | Dy/4 | 900/4 | 520/2 |
| Embodiment 5 | 48H | Pr₆₀Zn₂₀Cu₂₀/12 | Tb/5 | 920/4 | 500/2 |
| Embodiment 6 | 48H | Pr₆₀Ga₂₀Al₂₀/12 | Dy/5 | 900/4 | 520/2 |
| Embodiment 7 | 48H | Pr₆₀Fe₂₀Cu₂₀/14 | Tb/6 | 920/4 | 500/2 |
| Embodiment 8 | 48H | Pr₆₀Ni₂₀Al₂₀/14 | Dy/6 | 900/4 | 520/2 |
| Embodiment 9 | 48H | Pr₆₀Cu₂₀Zn₂₀/16 | Tb/7 | 920/4 | 500/2 |
| Embodiment 10 | 48H | Pr₆₀Cu₁₅Al₁₅Zn₁₀/16 | Dy/7 | 900/4 | 520/2 |

### Comparative Example 1

(1) The sintered Nd—Fe—B magnet (with the grade of 48H) is sliced into 8*8*7 mm blocks.

(2) The surfaces of the sintered Nd—Fe—B magnet block are cleaned, and it is ensured that the upper and lower polar surfaces of the sintered Nd—Fe—B magnet block are smooth and flat.

(3) Magnetron sputtering is performed on the upper and lower polar surfaces of the sintered Nd—Fe—B magnet block by using an alloy Cu₇₀Zn₃₀ as a target material when a vacuum degree is 1×10⁻³Pa to form an alloy film layer with a thickness of 16 μm on each of the upper and lower surfaces.

(4) Heavy rare earth Dy is deposited on the surface of each alloy film layer by magnetron sputtering technology when a vacuum degree is 1×10⁻³ Pa to acquire a heavy rare earth film layer with a thickness of 7 μm.

(5) A temperature at 920° C. is kept for 4 h and tempering is performed at 500° C. for 2 h when a vacuum degree is 2×10⁻³ Pa to acquire a high-coercivity sintered Nd—Fe—B magnetic material marked as material 11.

### Comparative Example 2

The preparation method in the comparative example 2 is the same as that in the comparative example 1, except that an alloy target material in (2) is Cu₇₀Al₃₀.

The morphology of the material acquired from each embodiment is characterized as follows.

Here, a testing method includes:

after the magnet is sliced along the height direction, its microstructure is scanned, wherein the scanning may be performed by a well-known field emission scanning electron microscope SEM. Observation is performed from the diffusion surface of the magnet toward the center of the magnet, and an observation range above 80 μm (length)×40 ƒm (width) is set to observe the micro-morphology of the material at different distances from the diffusion surface; or

after the magnet is sliced along the height direction, its microstructure is scanned, wherein the scanning may be performed by a well-known field emission scanning electron microscope SEM. Observation is performed from the diffusion surface of the magnet toward the center of the magnet, an observation range above 80 μm (length)×40 μm (width) is set, and the SEM is adopted to directly calibrate a phase size, so as to determine the size of the crystal grains, the thickness of the crystal grain shell, and the width of the thin-layer grain boundary phase.

Here, the material 1 provided by Embodiment 1 is taken as a typical representative for description, and the materials obtained from other embodiments all have the same or similar morphology.

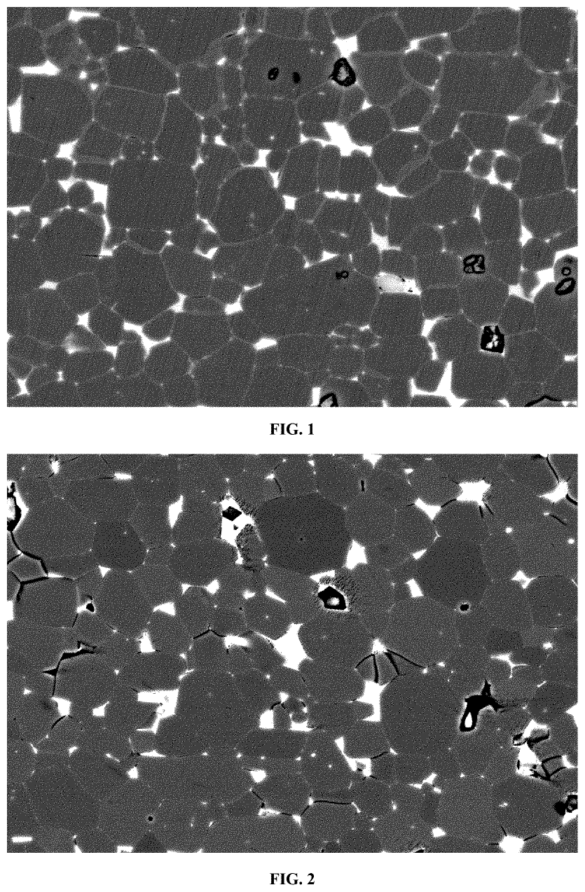

FIG. 1 is a slice electron microscope photograph in the range within 50 pm from the diffusion surface of the magnet. As shown in FIG. 1, the crystal grains in the material 1 are equiaxed crystals, and the crystal grain size is 2 μm to 20 μm. The main phase of the material 1 includes Nd₂Fe₁₄B, and the grain boundary phase of the material 1 includes a thin-layer grain boundary phase located between two crystal grains and a trifurcated grain boundary phase located at corners of multiple crystal grains. Referring to FIGS. 1 and 2, compared with the unmodified sintered Nd—Fe—B magnet, in the region within 50 μm from the diffusion surface of the sintered Nd—Fe—B magnet of the material 2, the thin-layer grain boundary phase is uniformly distributed between the crystal grains, the boundary between the crystal grains is clear, and the width of the thin-layer grain boundary phase is 50 nm to 500 nm. In the region within 50 μm from the diffusion surface of the sintered Nd—Fe—B magnet, the crystal grains are core-shell structure grains, and the thickness of the shell layer of the core-shell structure grain is 0.1 μm to 2.0 μm.

Properties of the materials acquired from all the embodiments and the comparative examples are tested.

The remanence, coercivity and magnetic energy product of each material are measured by NIM-500C magnetic tester at room temperature. The test results are shown in Table 2.

TABLE 2
Table of Magnetic Property Parameters of Materials Acquired
from All Embodiments and Comparative Examples

| | Remanence | Coercivity | Magnetic Energy |
|---|---|---|---|
| Embodiment | (T) | (kOe) | Product (MGOe) |
| Embodiment 1 | 1.39 | 25.6 | 46.8 |
| Embodiment 2 | 1.40 | 23.5 | 47.3 |
| Embodiment 3 | 1.41 | 25.9 | 47.3 |
| Embodiment 4 | 1.39 | 23.8 | 47.6 |
| Embodiment 5 | 1.38 | 26.6 | 48.0 |
| Embodiment 6 | 1.38 | 24.1 | 48.1 |
| Embodiment 7 | 1.39 | 27.2 | 47.5 |
| Embodiment 8 | 1.37 | 24.3 | 46.9 |
| Embodiment 9 | 1.37 | 28.0 | 46.4 |
| Embodiment 10 | 1.36 | 24.8 | 46.5 |
| Comparative example 1 | 1.37 | 23.4 | 46.2 |
| Comparative example 2 | 1.36 | 23.2 | 46.4 |
| Unmodified sintered | 1.41 | 18.2 | 48.5 |
| Nd—Fe—B magnet | | | |

It can be seen from Table 2 that the coercivity of the magnet materials provided by the embodiments of the present invention is increased by more than 29% with respect to the coercivity of 18.2 kOe before the grain boundary diffusion, while there is almost no drop in the remanence. Especially, the coercivity of the material 9 provided by Embodiment 9 is increased by nearly 54%; while the comparative examples 1 and 2 only increase the coercivity by 28.5% under the similar condition as that in Embodiment 9.

The present invention is described in detail above. The above embodiments are only preferred embodiments of the present invention, and should not limit the implementation scope of the present invention. That is, all equivalent changes and modifications made in accordance with the scope of the present application shall still fall within the scope of the present invention.

1. A modified sintered Nd—Fe—B magnet, wherein the modified sintered Nd—Fe—B magnet is prepared by performing grain boundary diffusion on a matrix; the matrix is a sintered Nd—Fe—B magnet; a grain boundary diffusion source for the grain boundary diffusion consists of a first diffusion source and a second diffusion source; the first diffusion source is a PrMx alloy, M is at least one selected from a group consisted of Cu, Al, Zn, Mg, Ga, Sn, Ag, Pb, Bi, Ni, Nb, Mn, Co, Fe, Ti, Cr, Zr, Mo and Ge, X represents a mass percentage and is 8 to 90, and the balance is Pr and an unavoidable impurity; and the second diffusion source is heavy rare earth Dy and/or Tb.

2. The modified sintered Nd—Fe—B magnet according to claim 1, wherein a mass ratio of the matrix, the first diffusion source, and the second diffusion source is 100:0.1-2:0.1-1.

3. The modified sintered Nd—Fe—B magnet according to claim 2, wherein crystal grains are equiaxed crystals, and a crystal grain size is 2 μm to 20 μm.

4. The modified sintered Nd—Fe—B magnet according to claim 2, wherein a grain boundary phase comprises a thin-layer grain boundary phase located between two crystal grains, the thin-layer grain boundary phase is distributed between the crystal grains in a region within 50 μm from a diffusion surface of the sintered Nd—Fe—B magnet, a boundary between the crystal grains is clear, and a width of the thin-layer grain boundary phase is 50 nm to 500 nm.

5. The modified sintered Nd—Fe—B magnet according to claim 4, wherein in the region within 50 μm from the diffusion surface of the sintered Nd—Fe—B magnet, the crystal grains are core-shell structure grains, and a thickness of a shell layer of the core-shell structure grain is 0.1 μm to 2.0 μm.

6. A preparation method of a modified sintered Nd—Fe—B magnet, at least comprising the following steps:
(1) preparing an alloy film layer on a surface of a sintered Nd—Fe—B magnet, wherein the alloy film layer is PrMx, M is at least one selected from a group consisted of Cu, Al, Zn, Mg, Ga, Sn, Ag, Pb, Bi, Ni, Nb, Mn, Co, Fe, Ti, Cr, Zr, Mo and Ge, X represents a mass percentage and is 8 to 90, and the balance is Pr and an unavoidable impurity;
(2) preparing a heavy rare earth film layer on the surface of the alloy film layer acquired in (1), wherein heavy rare earth comprises Dy and/or Tb; and
(3) acquiring the modified sintered Nd—Fe—B magnet by performing grain boundary diffusion on the sintered Nd—Fe—B magnet by using the alloy film layer and the heavy rare earth film layer as a diffusion source.

7. The preparation method according to claim 6, wherein a melting point of the alloy film layer in (1) is 400° C. to 700° C.

8. The preparation method according to claim 6, wherein a thickness of the alloy film layer in (1) is 1 μm to 40 μm.

9. The preparation method according to claim 6, wherein said preparing the alloy film layer in (1) specifically comprises:
depositing the alloy film layer by adopting magnetron sputtering technology and using a PrMₓ alloy as a target material under a condition that a vacuum degree is lower than 2×10⁻³ Pa.

10. The preparation method according to claim 6, wherein a thickness of the heavy rare earth film layer in (2) is 1 μm to 20 μm.

11. The preparation method according to claim 6, wherein said preparing the heavy rare earth film layer in (2) specifically comprises:
depositing the heavy rare earth film layer by adopting a magnetron sputtering method and using heavy rare earth as a target material under a condition that a vacuum degree is lower than 2×10⁻³ Pa.

12. The preparation method according to claim 6, wherein a specific condition for the grain boundary diffusion in (3) comprises:
a vacuum degree being lower than 3×10⁻³ Pa;
a diffusion temperature being 750° C. to 1000° C.; and
diffusion duration being 0.5 h to 24 h.

13. The preparation method according to claim 1, wherein after the grain boundary diffusion, tempering treatment is performed at 430° C. to 640° C. for 0.5 h to 10 h.

14. The preparation method according to claim 6, wherein a diffusion temperature is 850° C. to 950° C.; and
diffusion duration is 2 h to 24 h.

15. The preparation method according to claim 6, wherein a mass ratio of the sintered Nd—Fe—B magnet, the alloy film layer and the heavy rare earth film layer is 100:0.5-1:0.2-0.6.

16. A use of the modified sintered Nd—Fe—B magnet according to in fields of wind power generation, energy-saving home appliances and new energy vehicles.

17. A use of the modified sintered Nd—Fe—B magnet according to claim 2 in fields of wind power generation, energy-saving home appliances and new energy vehicles.

18. A use of the modified sintered Nd—Fe—B magnet according to claim 3 in fields of wind power generation, energy-saving home appliances and new energy vehicles.

19. A use of the modified sintered Nd—Fe—B magnet according to claim 4 in fields of wind power generation, energy-saving home appliances and new energy vehicles.

20. A use of the modified sintered Nd—Fe—B magnet according to claim 5 in fields of wind power generation, energy-saving home appliances and new energy vehicles.
